(19) United States
(12) Patent Application Publication
(10) Pub. No.: US 2007/0111467 A1
(43) Pub. Date: May 17, 2007

(54) Method for forming trench using hard mask with high selectivity and isolation method for semiconductor device using the same

(76) Inventor: Myung-Ok Kim, Kyoungki-do (KR)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/403,065

(22) Filed: Apr. 11, 2006

(30) Foreign Application Priority Data
Nov. 12, 2005 (KR) 2005-0108315

(51) Int. Cl. H01L 21/762; H01L 21/467

(52) U.S. Cl. 438/424; 438/717; 438/725; 438/736

(57) ABSTRACT

Provided are a method for forming a trench using a hard mask with high selectivity and an isolation method for a semiconductor device using the same. The method includes: forming a first hard mask over a substrate, the first hard mask including an oxide layer and a nitride layer; forming a second hard mask with high selectivity over the first hard mask; forming an etch barrier layer and an anti-reflective coating layer over the second hard mask; forming a photosensitive pattern over the anti-reflective coating layer; etching the anti-reflective coating layer, the etch barrier layer and the second hard mask using the photosensitive pattern as an etch barrier; etching the first hard mask and the substrate using the second hard mask as an etch barrier to form a trench; and removing the second hard mask.

### FIELD OF THE INVENTION

The present invention relates to a method for fabricating a semiconductor device; and, more particularly, to a method for forming a trench in-situ using a hard mask with high selectivity and an isolation method for a semiconductor device using the same.

### DESCRIPTION OF RELATED ARTS

Recently, a shallow trench isolation (STI) method is frequently used as a device isolation method for semiconductor devices to meet the demands of large scale integration. For device isolation using the STI method, a pad oxide layer and a pad nitride layer are generally used and etched using a device isolation mask, based on a photosensitive material, as an etch barrier. A substrate is etched to a certain depth using the patterned pad nitride layer as a hard mask to form a trench, which becomes a device isolation region.

FIGS. 1A and 1B are simplified cross-sectional views illustrating a device isolation method for a semiconductor device using a conventional STI method.

Referring to FIG. 1A, a pad oxide layer 12 and a pad nitride layer 13 are sequentially formed on a substrate 11. A photosensitive layer is formed on the pad nitride layer 13 and exposed to light and developed to be formed as a device isolation mask 14. Using the device isolation mask 14 as an etch barrier, the pad nitride layer 13 and the pad oxide layer 12 are sequentially etched in an etch chamber for an oxide material (hereinafter “oxide etch chamber”).

Referring to FIG. 1B, the substrate 11 is etched using the device isolation mask 14 as an etch barrier in an etch chamber for a polysilicon material (hereinafter “polysilicon etch chamber”). As a result, trenches 15 are formed. The etching process for forming the trenches 15 is carried out ex-situ by transferring the etching from the oxide etch chamber to the polysilicon etch chamber. The device isolation mask 14 is stripped and a cleaning process is performed thereafter.

Since the photosensitive material is used to form the trenches 15, this STI method is particularly called photosensitive material based barrier STI method. However, since the above two etching processes are performed in an ex-situ condition, manufacturing processes may become complicated. For instance, the convention STI method includes four sequential processes including an etching process for hard masks (e.g., a pad nitride layer), an etching process for trenches, a stripping of a photosensitive material, and a cleaning process. Because of the complicated manufacturing processes, the total processing time may also become elongated. As a result, manufacturing costs may increase.

After the etching process for the hard masks (e.g., a pad oxide layer or a pad nitride layer), the etching process for forming the trenches are performed at a different etch chamber from the etch chamber at which the hard mask etching process is performed, i.e., in an ex-situ condition. Hence, the processing time tends to be elongated, often causing generation of a native oxide layer or polymers. The generation of the native oxide layer or the polymers may result in a depth variation of the trenches.

FIG. 2 is a micrographic image of a damaged pad nitride layer. FIG. 3 is a micrographic image of a sloped profile of a pad nitride layer.

As illustrated in FIGS. 2 and 3, because the photoresist material has low selectivity, the pad nitride layer is more likely to be damaged (refer to ‘16’ in FIG. 2) or be sloped (refer to ‘17’ in FIG. 3). The damaged pad nitride layer 16 and the sloped profile 17 of the pad nitride layer may cause a depth variation. As a result, for highly integrated devices, it may be difficult to use the pad nitride layer for a device isolation method.

### SUMMARY OF THE INVENTION

It is, therefore, an object of the present invention to provide a method for forming a trench while reducing depth variation of the trench, usually caused by etching processes performed in an ex-situ condition, and damage to a pad nitride layer or a sloped profile of the pad nitride layer and an isolation method for a semiconductor device using the same.

In accordance with an aspect of the present invention, there is provided a method for forming a trench in a semiconductor device, including: forming a first hard mask over a substrate, the first hard mask including an oxide layer and a nitride layer; forming a second hard mask with high selectivity over the first hard mask; forming an etch barrier layer and an anti-reflective coating layer over the second hard mask; forming a photosensitive pattern over the anti-reflective coating layer; etching the anti-reflective coating layer, the etch barrier layer and the second hard mask using the photosensitive pattern as an etch barrier; etching the first hard mask and the substrate using the second hard mask as an etch barrier to form a trench; and removing the second hard mask.

In accordance with another aspect of the present invention, there is provided a method for isolating devices in a semiconductor device, including: sequentially forming a pad oxide layer and a pad nitride layer over a substrate; forming an amorphous carbon layer over the pad nitride layer; sequentially forming an etch barrier layer and an anti-reflective coating layer over the amorphous carbon layer; forming a photosensitive pattern over the anti-reflective coating layer; sequentially etching the anti-reflective coating layer, the etch barrier layer and the amorphous carbon layer using the photosensitive pattern as an etch barrier; sequentially etching the pad nitride layer, the pad oxide layer and the substrate using the amorphous carbon layer as an etch barrier to form a trench; removing the amorphous carbon layer; forming an insulation layer to fill the trench; and removing the pad nitride layer.

### BRIEF DESCRIPTION OF THE DRAWINGS

The above and other objects and features of the present invention will become better understood with respect to the following description of the exemplary embodiments given in conjunction with the accompanying drawings, in which:

FIGS. 1A and 1B are simplified cross-sectional views illustrating a device isolation method using a conventional STI method;

FIG. 2 is a micrographic image of a damaged pad nitride layer when the conventional device isolation method is employed;

FIG. 3 is a micrographic image of a sloped pad nitride layer when the conventional device isolation method is employed;

FIGS. 4A to 4H are cross-sectional views illustrating an isolation method for a semiconductor device in accordance with an embodiment of the present invention; and

FIG. 5 shows micrographic images of a resultant structure after an in-situ STI method in accordance with an embodiment of the present invention.

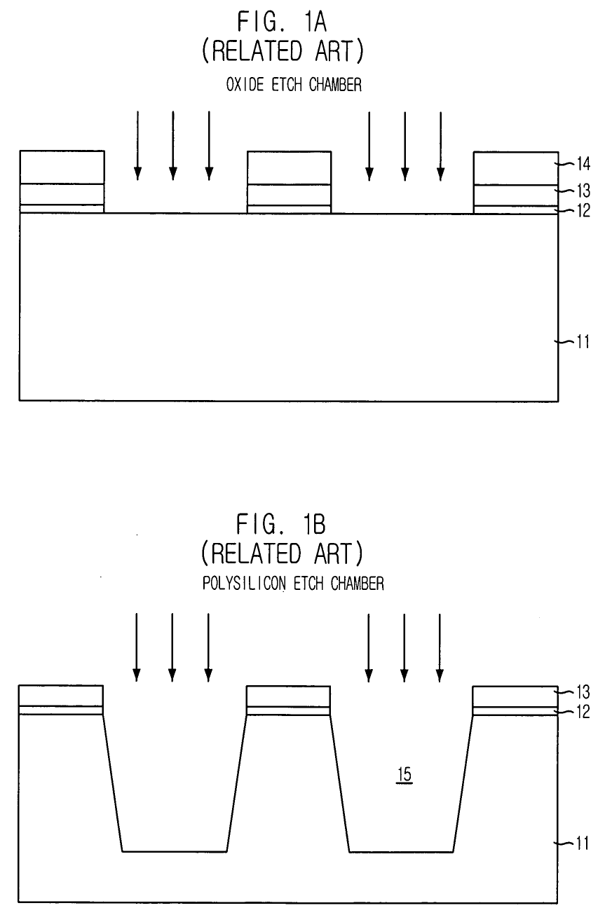

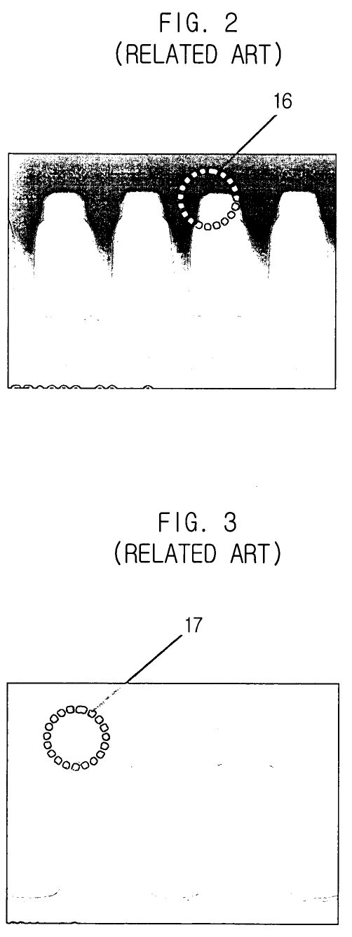

### DETAILED DESCRIPTION OF THE INVENTION

Exemplary embodiments of the present invention will be described in detail with reference to the accompanying drawings.

A device isolation method using an in-situ STI method is suggested in an embodiment of the present invention. Particularly, the suggested in-situ STI method uses a hard mask with high selectivity (e.g., amorphous carbon). A stack structure of a pad oxide layer and a pad nitride layer is referred as a first hard mask, and an amorphous carbon layer is formed as a second hard mask over the first hard mask. The amorphous carbon layer serves as an etch barrier when the pad nitride layer is etched as well as when a substrate (e.g., a silicon based substrate) is etched to form a trench. When the silicon substrate is etched using the amorphous carbon layer, since the amorphous layer has high selectivity, the amorphous carbon layer is not etched away till the trench is formed. The remaining amorphous carbon layer reduces damage to the pad nitride layer, i.e., the first hard mask.

Hereinafter, the device isolation method will be described in detail with reference to the accompanying drawings.

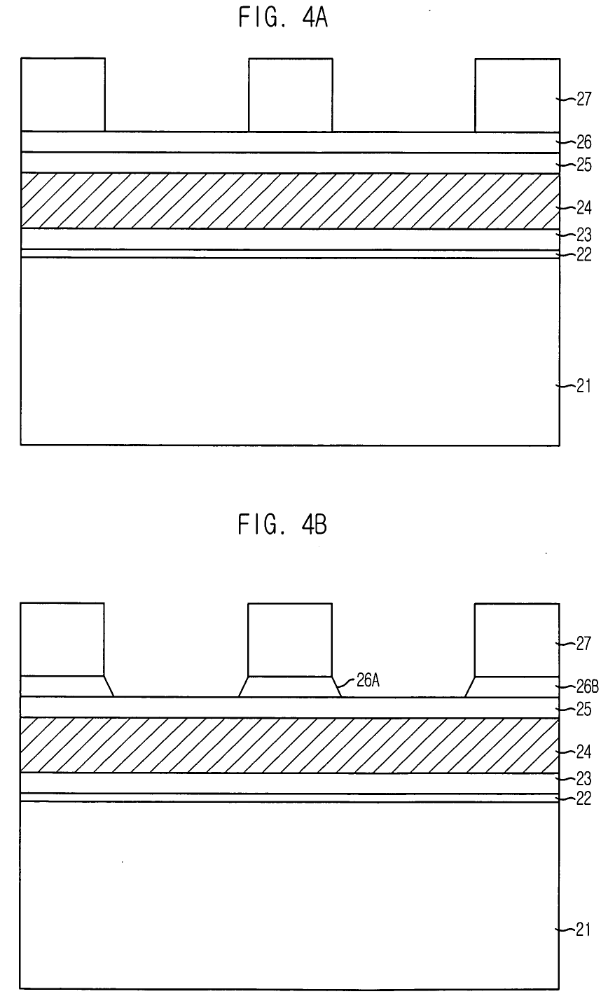

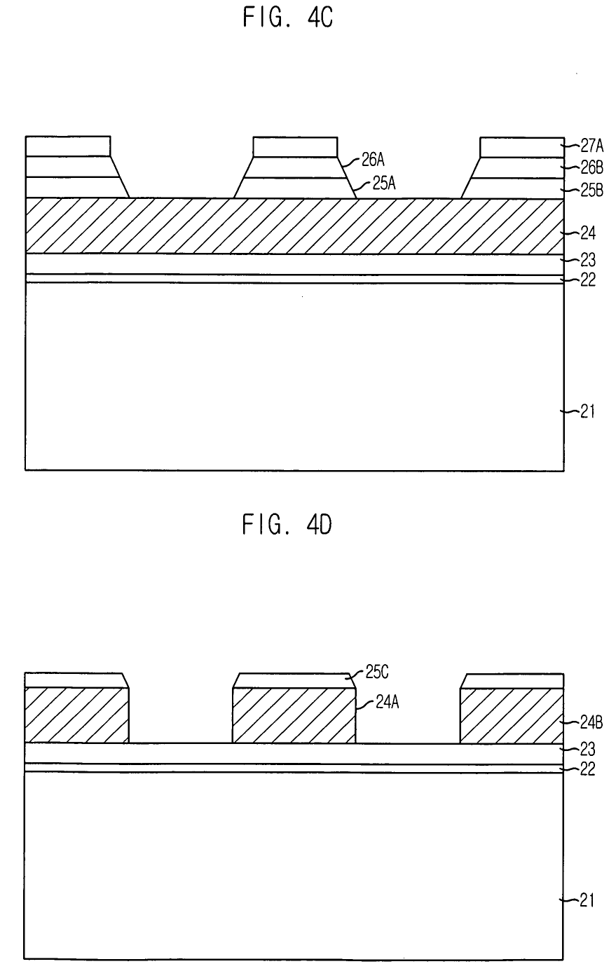

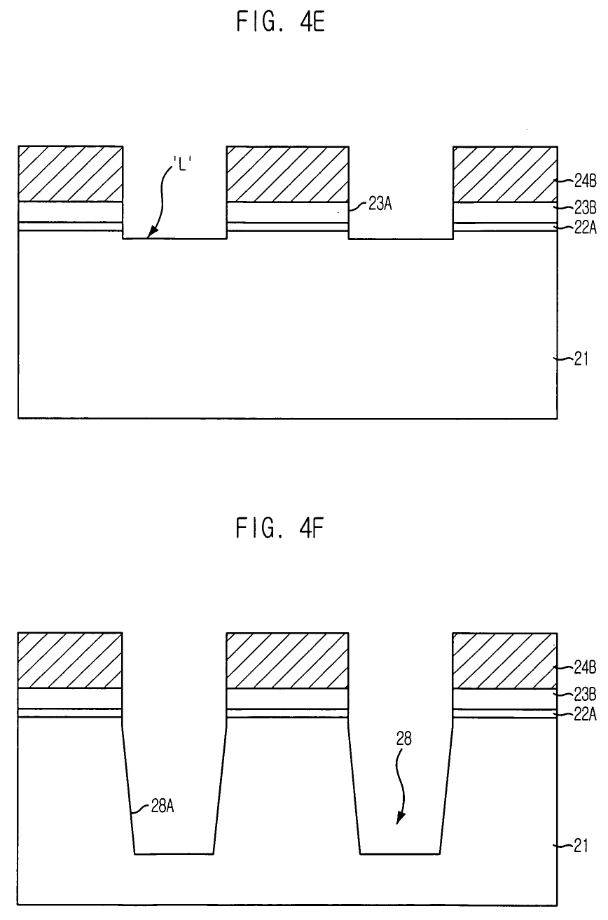

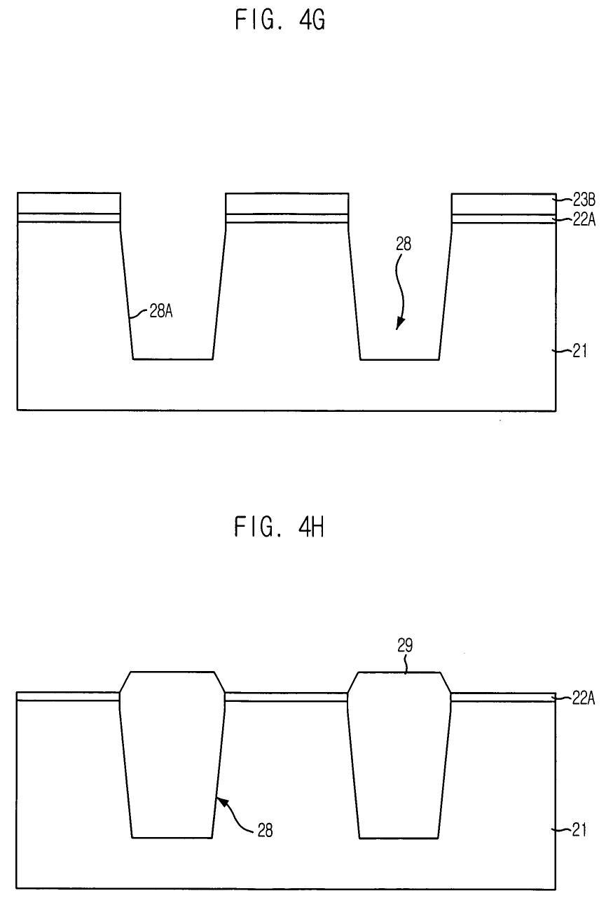

FIGS. 4A to 4H are cross-sectional views illustrating an isolation method for a semiconductor device in accordance with an embodiment of the present invention.

Referring to FIG. 4A, a pad oxide layer 22 is formed over a substrate 21 by performing a thermal oxidation process. The pad oxide layer 22 is formed to a thickness ranging from approximately 50 Å to approximately 300 Å. A chemical vapor deposition (CVD) method is employed to form a pad nitride layer 23 and an amorphous carbon layer 24 sequentially over the pad oxide layer 22. The pad nitride layer 23 has a thickness ranging from approximately 400 Å to approximately 800 Å. The amorphous carbon layer 24 is formed at approximately 300° C. to approximately 600° C. and has a thickness ranging from approximately 1,000 Å to approximately 5,000 Å. The thickness of the amorphous carbon layer 24 can be changed according to the depth of a trench to be formed by etching the substrate 21 (e.g., the silicon based substrate).

A silicon oxynitride layer 25 is formed over the amorphous carbon layer 24 in a thickness of approximately 200 A to approximately 800 Å. The silicon oxynitride layer 25 serves a role in reducing an etching of the amorphous carbon layer 24 due to loss of a device isolation mask 27 and an anti-reflective coating layer 25 while performing an etching process on the amorphous carbon layer 24. That is, the silicon oxynitride layer 25 serves as an etch barrier layer. The above mentioned anti-reflective coating layer 26 is formed over the silicon oxynitride layer 25, and particularly, the anti-reflective coating layer 26 includes an organic material. For instance, the anti-reflective coating layer 26 is formed of a material including carbon and hydrogen. The silicon oxynitride layer 25 is formed based on a CVD method, and the thickness of the silicon oxynitride layer 25 can be changed depending on the thicknesses of the amorphous carbon layer 24 and the pad nitride layer 23.

The above mentioned device isolation mask 27 is formed over the anti-reflective coating layer 26. More specifically, although not illustrated, a photosensitive material is formed over the anti-reflective coating layer 26 and patterned through a photo-exposure and developing process.

The anti-reflective coating layer 26, the silicon oxynitride layer 25, the amorphous carbon layer 24, the pad nitride layer 23, the pad oxide layer 22, and the substrate 21 are sequentially etched to form trenches. These sequential etching processes are carried out in-situ and often referred to as “in-situ STI process.” Particularly, the in-situ STI process is carried out at a polysilicon etch chamber using transformer coupled plasma (TCP) as a plasma source. That is, these sequential etching processes are performed in the same polysilicon etch chamber.

Detailed description of the sequential etching processes will be provided hereinafter.

Referring to FIG. 4B, the anti-reflective coating layer 26 is etched using the device isolation mask 27 as an etch barrier. The etching of the anti-reflective coating layer 26 is carried out at a condition of: a pressure of approximately 5 mTorr to approximately 40 mTorr; a top power higher than at least twice a bottom power; and a mixture gas of CF₄/CHF₃/O₂. As an exemplary condition of the top power and the bottom power, the top power may range from approximately 300 W to approximately 900 W, and the bottom power may range from approximately 20 W to approximately 400 W. Also, the anti-reflective coating layer 26 is etched at an angle of approximately 80 degrees or less (e.g., approximately 70 degrees to approximately 80 degrees). Reference numeral 26A denotes this sloped etch profile of the anti-reflective coating layer 26, and reference numeral 26B denotes a patterned anti-reflective coating layer.

When the anti-reflective coating layer 26 is etched, a flow quantity of the CHF₃ gas of the mixture gas is set to be higher than that of the CF₄ gas by at least approximately 4-fold or above, for instance, approximately 4-fold to approximately 6-fold to set a condition of generating lots of polymers. For instance, the flow quantity of the CF₄ gas ranges from approximately 5 sccm to approximately 20 sccm, and the flow quantity of the CHF₃ gas ranges from approximately 20 sccm to approximately 120 sccm. The O₂ gas has a flow quantity of approximately 0 sccm to approximately 20 sccm. Under this condition, the anti-reflective coating layer 26 can have the sloped etch profile 26A.

Referring to FIG. 4C, the silicon oxynitride layer 25 is etched at a condition of: a pressure of approximately 5 mTorr to approximately 40 mTorr; a top power higher than a bottom power by at least 2-fold to 3-fold; and a mixture gas of CF₄/CH₂F₂ or CF₄/CHF₃. As an exemplary condition for the top power and the bottom power, the top power may range from approximately 300 W to approximately 900 W, and the bottom power may range from approximately 20 W to approximately 400 W. The etching of the silicon oxynitride layer 25 is particularly performed to make the silicon oxynitride layer 25 be etched at an angle of approximately 80 degrees or less (e.g., approximately 70 degrees to approximately 80 degrees), so that the etch profile of the silicon oxynitride layer 25 is sloped maximally.

For the etching of the silicon oxynitride layer 25, a flow quantity of the CH₂F₂ or CHF₃ gas is maintained to be higher than that of the CF₄ gas by at least 2-fold or above to realize the maximally sloped etch profile. For instance, the flow quantity of the CF₄ gas may range from approximately 5 sccm to approximately 40 sccm; the flow quantity of the CH₂F₂ gas may range from approximately 10 sccm to approximately 80 sccm; and the flow quantity of the CHF₃ gas ranges from approximately 10 sccm to approximately 120 sccm. Reference numerals 25A and 25B denote the sloped etch profile of the silicon oxynitride layer 25 and a patterned silicon oxynitride layer, respectively.

When the etching of the silicon oxynitride layer 25 is completed, the device isolation mask 27 is almost removed. Reference number 27A denotes a remaining device isolation mask, which is removed while the amorphous carbon layer 24 is etched.

The reason for making the etch profile of the anti-reflective coating layer 26 and the silicon oxynitride layer 25 be sloped is to form trenches in micronized patterns. For reference, the amorphous carbon layer 24 and the pad nitride layer 23 are to be etched to have a vertical etch profile for the purpose of obtaining an intended shape and depth of the trenches.

Referring to FIG. 4D, the amorphous carbon layer 24 is etched using a mixture gas under a specific condition of: a pressure of approximately 20 mTorr or less (e.g., in a range from approximately 3 mTorr to approximately 20 mTorr); a top power of approximately 300 W to approximately 800 W; and a bottom power of approximately 100 W to approximately 500 W. The mixture gas is selected from the group consisting of N₂/O₂, N₂/O₂/HBr/Cl₂ and N₂/N₂/CHF₃. At this point, each of the N₂ gas and the O₂ gas has a flow quantity ranging from approximately 50 sccm to approximately 200 sccm; each of the HBr gas, the Cl₂ gas and the CHF₃ gas has a flow quantity ranging from approximately 10 sccm to approximately 100 sccm; and the H₂ has a flow quantity ranging from approximately 50 sccm to approximately 200 sccm. As mentioned above, the amorphous carbon layer 24 is etched to have an etch profile 24A sloped at an angle of at least approximately 89 degrees or larger (e.g., in a range between approximately 89 degrees to approximately 90 degrees). That is, the etch profile 24A is substantially vertical. Reference numeral 24B denotes a patterned amorphous carbon layer, i.e., the second hard mask.

After the etching of the amorphous carbon layer 24, the remaining device isolation mask 27A and the patterned anti-reflective coating layer 26B do not remain, but a portion of the patterned silicon oxynitride layer 25B remains with a small thickness. Reference numeral 25C denotes this remaining portion of the silicon oxynitride layer 25 over the patterned amorphous carbon layer 24B.

The silicon oxynitride layer 25 formed beneath the anti-reflective coating layer 26 protects an upper surface of the amorphous carbon layer 24 from being etched during the etching of the amorphous carbon layer 24. For reference, when the anti-reflective coating layer 26 is etched, a portion of the device isolation mask 27 is etched away, and if the amorphous carbon layer 24 is etched using the remaining device isolation mask 27A and the patterned anti-reflective coating layer 26B as an etch barrier in the absence of the silicon oxynitride layer 25, the remaining device isolation mask 27A and the patterned anti-reflective coating layer 26B are simultaneously removed since the remaining device isolation mask 27A and the patterned anti-reflective coating layer 26B have no specific selectivity to the amorphous carbon layer 24. As a result, the amorphous carbon layer 24 is often damaged. However, even if the remaining device isolation mask 27A and the patterned anti-reflective coating layer 26 are etched away, the silicon oxynitride layer 25 formed between the amorphous carbon layer 24 and the anti-reflective coating layer 26 can reduce the damage to the amorphous carbon layer 24 since the silicon oxynitride layer 25 has selectivity to the amorphous carbon layer 24.

Referring to FIG. 4E, the pad nitride layer 23 is etched using the patterned amorphous carbon layer 24B as a hard mask under a specific condition of: a pressure of approximately 20 mTorr or less (e.g., in a range from approximately 3 mTorr to approximately 20 mTorr); a top power and a bottom power both being applied at a similar level ranging from approximately 300 W to approximately 800 W; and a gas selected from the group consisting of CF₄, CH₂F₂, O₂, He, and a mixture thereof. At this point, the pad nitride layer 23 is etched to have an etch profile 23A, which is substantially vertical ranging at an angle of approximately 89 degrees or larger (e.g., in a range from approximately 89 degrees to approximately 90 degrees). Reference numeral 23B denotes a patterned pad nitride layer after the above etching process.

Using the gas selected from the aforementioned group reduces generation of polymers, and thus, the pad nitride layer 23 can have a vertical etch profile. Since the patterned amorphous carbon layer 24B, which has high selectivity, is used as an etch barrier (i.e., the second hard mask) for etching the pad nitride layer 23, the pad nitride layer 23 can have the vertical etch profile 23A.

During the etching of the pad nitride layer 23, the remaining silicon oxynitride layer 25C over the patterned amorphous carbon layer 24 has a thickness smaller than the pad nitride layer 23, and thus, the remaining silicon oxynitride layer 25C is removed while the pad nitride layer 23 is etched.

Particularly, an over etching process is performed on the pad nitride layer 23 to remove the pad nitride layer 23. Particularly, the over etching process is carried out until the substrate 21 is etched to a depth L ranging from approximately 100 Å to approximately 200 Å. In more detail, as the pad nitride layer 23 is over etched, the pad oxide layer 22 is etched, and portions of the substrate 21, which are exposed as the pad oxide layer 22 is etched, are also etched to the above mentioned depth L (i.e., approximately 100 Å to approximately 200 Å). Reference numeral 22A denotes a patterned pad oxide layer after the above over etching process.

Referring to FIG. 4F, using the patterned amorphous carbon layer 24B remaining after the over etching process as an etch barrier, the exposed portions of the substrate 21 are etched to a predetermined depth ranging from approximately 2,000 Å to approximately 3,000 Å. As a result, the above mentioned trenches 28 are formed. This etching process of forming the trenches 28 is particularly referred to as “silicon trench etching process.”

For the silicon trench etching process, a mixture gas selected from the group consisting of Cl₂/O₂, HBr/O₂ and HBr/Cl₂/O₂ is used, and during the silicon trench etching process, a pressure, a top power, a bottom power, a ratio of gas flow quantity can be adjusted depending on an intended shape of a slope 28A of the trench 28. In almost all cases, since the patterned amorphous carbon layer 24B has high selectivity, the patterned pad nitride layer 23B is not likely to be damaged.

In other words, even if the process condition of the silicon trench etching process is changed, the patterned amorphous carbon layer 24B has high selectivity to the mixture gas selected from the group consisting of Cl₂/O₂, HBr/O₂ and HBr/Cl₂/O₂. Thus, the patterned amorphous carbon layer 24B remains until the trenches 28 are formed, and as a result, the patterned pad nitride layer 23B is not likely to be damaged and a change in the etch profile 23A of the pad nitride layer 23 can be reduced.

For instance, the silicon trench etching process is carried out under a specific condition of: a pressure of approximately 20 mTorr or less (e.g., in a range from approximately 3 mTorr to approximately 20 mTorr); a top power of approximately 300 W to approximately 800 W; a bottom power of approximately 100 W to approximately 400 W; O₂ gas with a flow quantity of approximately 50 sccm to approximately 200 sccm; HBr gas with a flow quantity of approximately 10 sccm to approximately 100 sccm; Cl₂ gas with a flow quantity of approximately 10 sccm to approximately 100 sccm. Under this condition, the patterned amorphous carbon layer 24B has high selectivity. Even if the silicon trench etching process is performed by changing the pressure, top power, bottom power, and the flow quantities of the etch gases, the patterned amorphous carbon layer 24B still has high selectivity.

Referring to FIG. 4G, a cleaning process is performed to remove the patterned amorphous carbon layer 24B remaining after the trenches 28 are formed. The cleaning process may be performed in-situ in the same chamber where the sequential processes up to the formation of the trenches 28 or ex-situ in the different chamber. Also, the cleaning process uses a plasma using O₂ gas solely or a mixture gas selected from the group consisting of O₂/N₂, N₂/H₂, and O₂/CF₄.

After the removal of the patterned amorphous carbon layer 24B, the in-situ STI process is completed.

Referring to FIG. 4H, an insulation layer 29 is formed to fill the trenches 28. Hereinafter, the insulation layer 29 will be referred to as “gap-fill insulation layer.” Then, a chemical mechanical polishing (CMP) process is performed on the gap-fill insulation layer 29 for isolation. A strip process is then performed to remove the patterned pad nitride layer 23B. As a result of these sequential processes, trench type device isolation structures are formed. The gap-fill insulation layer 29 includes high density plasma oxide, and the strip process is carried out using a solution of phosphoric acid (H₃PO₄).

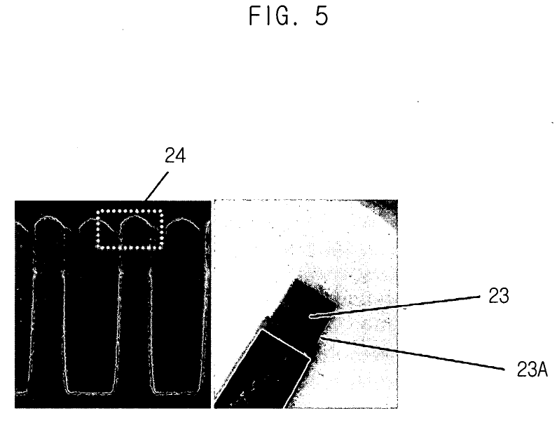

FIG. 5 is a micrographic image of a resultant structure after an in-situ STI method in accordance with an embodiment of the present invention. Herein, the same reference numerals denote the same elements described in FIGS. 4A to 4H.

After trenches are formed, the amorphous carbon layer 24 remains, and thus, the pad nitride layer 23 is not likely to be damaged. Also, the etch profile 23A of the pad nitride layer 23 is substantially vertical.

On the basis of the embodiments of the present invention, the etching process for forming the trenches for device isolation (i.e., the in-situ STI method) includes the sequential etching of the anti-reflective coating layer 26, the silicon oxynitride layer 25, the amorphous carbon layer 24, the pad nitride layer 23, the pad oxide layer 22, and the portions of the substrate 21 where the trenches 28 are to be formed. These sequential etching processes are performed in-situ. Particularly, the in-situ STI method is performed at a polysilicon etcher using TCP as a plasma source, and these sequential etching processes are performed sequentially in the same polysilicon etch chamber.

The in-situ etching reduces a time delay in execution of the related processes, and thus, a native oxide layer and polymers are not generated, further resulting in no variation in the depth of the trenches. Also, the in-situ STI method using the amorphous carbon layer as a hard mask makes it possible to reduce damage to the pad nitride layer and a generation of a sloped etch profile of the pad nitride layer, both often caused by low selectivity of the photosensitive material used as an etch mask.

As mentioned above, the trenches are typically obtained by performing four sequential processes including etching the pad nitride layer, forming the trenches, stripping the photosensitive material and cleaning the remnants. In contrast, the trenches according to the present embodiment can be obtained through a simplified process including the in-situ STI process using the amorphous carbon layer as a hard mask and the cleaning process. The simplified process shortens a turn around time (TAT), contributing to a cost reduction.

The in-situ STI method according to the exemplary embodiment of the present invention can overcome limitations of the conventional STI method using a typical photosensitive material as an etch mask. That is, it is possible to reduce variation in critical dimension and depth, damage to the pad nitride layer and a sloped etch profile of the pad nitride layer. As a result, the in-situ STI method can be implemented to 50 nm level semiconductor technology.

The present application contains subject matter related to the Korean patent application No. KR 2005-0108315, filed in the Korean Patent Office on Nov. 12, 2005, the entire contents of which being incorporated herein by reference.

While the present invention has been described with respect to certain preferred embodiments, it will be apparent to those skilled in the art that various changes and modifications may be made without departing from the spirit and scope of the invention as defined in the following claims.

What is claimed is:

1. A method for forming a trench in a semiconductor device comprising:
forming a first hard mask over a substrate, the first hard mask including an oxide layer and a nitride layer;
forming a second hard mask with high selectivity over the first hard mask;
forming an etch barrier layer and an anti-reflective coating layer over the second hard mask;
forming a photosensitive pattern over the anti-reflective coating layer;
etching the anti-reflective coating layer, the etch barrier layer and the second hard mask using the photosensitive pattern as an etch barrier;
etching the first hard mask and the substrate using the second hard mask as an etch barrier to form a trench; and
removing the second hard mask.

2. The method of claim 1, wherein the second hard mask includes an amorphous carbon layer.

3. The method of claim 2, wherein the etching of the anti-reflective coating layer, the etch barrier layer and the second hard mask and the etching of the first hard mask and the substrate to form the trench are carried out in-situ in the same chamber.

4. The method of claim 2, wherein the etching of the anti-reflective coating layer, the etch barrier layer and the second hard mask, the etching of the first hard mask and the substrate to form the trench and the removal of the second hard mask are performed in-situ in the same chamber.

5. The method of claim 2, wherein the etching of the anti-reflective coating layer, the etch barrier layer and the second hard mask and the etching of the first hard mask and the substrate to form the trench are performed in-situ in the same chamber and the removal of the second hard mask are performed ex-situ in a different chamber.

6. The method of claim 5, wherein the chamber where the etching of the anti-reflective coating layer, the etch barrier layer and the second hard mask and the etching of the first hard mask and the substrate are performed in-situ is a polysilicon etch chamber.

7. The method of claim 1, wherein the etch barrier layer includes a silicon oxynitride layer.

8. The method of claim 1, wherein the etching of the anti-reflective coating layer, the etch barrier layer and the second hard mask comprises etching the anti-reflective coating layer and the etch barrier layer to have an etch profile sloped at an angle of approximately 80 degrees or less.

9. The method of claim 8, wherein the etching of the second hard mask comprises etching the second hard mask to have a vertical etch profile.

10. A method for isolating devices in a semiconductor device comprising:
sequentially forming a pad oxide layer and a pad nitride layer over a substrate;
forming an amorphous carbon layer over the pad nitride layer;
sequentially forming an etch barrier layer and an anti-reflective coating layer over the amorphous carbon layer;
forming a photosensitive pattern over the anti-reflective coating layer;
sequentially etching the anti-reflective coating layer, the etch barrier layer and the amorphous carbon layer using the photosensitive pattern as an etch barrier;
sequentially etching the pad nitride layer, the pad oxide layer and the substrate using the amorphous carbon layer as an etch barrier to form a trench;
removing the amorphous carbon layer;
forming an insulation layer to fill the trench; and
removing the pad nitride layer.

11. The method of claim 10, wherein the sequential etching of the anti-reflective coating layer, the etch barrier layer and the amorphous carbon layer and the sequential etching of the pad nitride layer, the pad oxide layer and the substrate to form the trench are performed in situ in the same chamber.

12. The method of claim 10, wherein the sequential etching of the anti-reflective coating layer, the etch barrier layer and the amorphous carbon layer, the sequential etching of the pad nitride layer, the pad oxide layer and the substrate to form the trench and the removal of the amorphous carbon layer are performed in-situ in the same chamber.

13. The method of claim 10, wherein the sequential etching of the anti-reflective coating layer, the etch barrier layer and the amorphous carbon layer and the sequential etching of the pad nitride layer, the pad oxide layer and the substrate to form the trench are performed in-situ in the same chamber and the removal of the amorphous carbon layer is performed ex-situ in a different chamber.

14. The method of claim 13, wherein the chamber where the sequential etching of the anti-reflective coating layer, the etch barrier layer and the amorphous carbon layer and the sequential etching of the pad nitride layer, the pad oxide layer and the substrate to form the trench are performed in-situ is a polysilicon etch chamber.

15. The method of claim 10, wherein the etching of the anti-reflective coating layer comprises etching the anti-reflective coating layer to have an etch profile sloped at an angle of approximately 80 degrees or less under a specific condition of: a pressure of approximately 5 mTorr to approximately 40 mTorr; a top power applied higher than a bottom power by at least approximately 2-fold; and a mixture gas of CF₄/CHF₃/O₂.

16. The method of claim 15, wherein the etching of the anti-reflective coating layer comprises using the top power ranging from approximately 300 W to approximately 900 W and the bottom power ranging from approximately 20 W to approximately 400 W.

17. The method of claim 15, wherein the CHF₃ gas of the mixture gas has a flow quantity higher than the CF₄ gas of the mixture gas by at least approximately 4-fold.

18. The method of claim 17, wherein the flow quantity of the CF₄ gas ranges from approximately 5 sccm to approximately 20 sccm; the flow quantity of the CHF₃ gas ranges from approximately 20 sccm to approximately 120 sccm; and the flow quantity of the O₂ gas ranges from approximately 0 sccm to approximately 20 sccm.

19. The method of claim 10, wherein the etch barrier layer includes a silicon oxynitride layer.

20. The method of claim 19, wherein the etching of the etch barrier layer comprises etching the etch barrier layer to have an etch profile sloped at an angle of approximately 80 degrees or less under a specific condition of: a pressure of approximately 5 mTorr to approximately 40 mTorr; a top power applied higher than a bottom power by at least approximately 2-fold to 3-fold; and a mixture gas selected one of CF₄/CHF₃ and CF₄/CH₂F₂.

21. The method of claim 20, wherein the etching of the etch barrier layer comprises using the top power ranging from approximately 300 W to approximately 900 W and the bottom power ranging from approximately 20 W to approximately 400 W.

22. The method of claim 20, wherein the CH₂F₂ gas or the CHF₃ gas of the mixture gas has a flow quantity higher than the CF₄ gas of the mixture gas by at least approximately 2-fold.

23. The method of claim 22, wherein the flow quantity of the CF₄ gas ranges from approximately 5 sccm to approximately 40 sccm; the flow quantity of the CH₂F₂ gas ranges from approximately 10 sccm to approximately 80 sccm; and the flow quantity of the CHF₃ gas ranges from approximately 10 sccm to approximately 120 sccm.

24. The method of claim 10, wherein the etching of the amorphous carbon layer comprises etching the amorphous carbon layer to have an etch profile being substantially vertical under a specific condition of: a pressure of approximately 3 mTorr to approximately 20 mTorr; a top power of approximately 300 W to approximately 800 W; a bottom power of approximately 100 W to approximately 500 W; and a mixture gas selected from the group consisting of N₂/O₂, N₂/O₂/HBr/Cl₂ and N₂/H₂/CHF₃.

25. The method of claim 10, wherein the etching of the pad nitride layer comprises etching the pad nitride layer to have an etch profile being substantially vertical under a specific condition of: a pressure of approximately 3 mTorr to approximately 20 mTorr; a top power of approximately 300 W to approximately 800 W; a bottom power of approximately 300 W to approximately 800 W; and a gas selected from the group consisting of CF₄, CH₂F₂, O₂, He, and a mixture thereof.

26. The method of claim 25, wherein the etching of the pad nitride layer comprises over etching the pad nitride layer so as to etch the pad oxide layer and a portion of the substrate.

27. The method of 26, wherein the etching of the portion of the substrate comprises etching the portion of the substrate to a thickness ranging from approximately 100 Å to approximately 200 Å.

28. The method of claim 10, wherein the forming of the trench comprises using a mixture gas selected from the group consisting of Cl₂/O₂, HBr/O₂ and HBr/Cl₂/O₂.

29. The method of claim 13, wherein the removal of the amorphous carbon layer comprises using a plasma using one of O₂ gas and a mixture gas selected from the group consisting of O₂/N₂, N₂/H₂ and O₂/CF₄.

30. The method of claim 10, wherein the amorphous carbon layer is formed by performing a chemical vapor deposition (CVD) method at a temperature ranging from approximately 300° C. to approximately 600° C., wherein the amorphous carbon layer has a thickness ranging from approximately 1,000 Å to approximately 5,000 Å.
